(19) United States
(12) Patent Application Publication
(10) Pub. No.: US 2023/0246067 A1
(43) Pub. Date: Aug. 3, 2023

(54) ENABLING BOTTOM ISOLATION AND EPITAXIAL STRAIN OF FET SOURCE/DRAIN STRUCTURES

(71) Applicant: International Business Machines Corporation, Armonk, NY (US)

(72) Inventors: Jingyun Zhang, Singerlands, NY (US); Ruqiang Bao, Niskayuna, NY (US); Sung Dae Suk, Watervliet, NY (US)

(21) Appl. No.: 17/592,479

(22) Filed: Feb. 3, 2022

(51) Int. Cl. H01L 29/06; H01L 29/423; H01L 29/786; H01L 29/66; H01L 21/8234; H01L 21/762

(52) U.S. Cl. CPC H01L 29/0653; H01L 29/0665; H01L 29/42392; H01L 29/78618; H01L 29/78696; H01L 29/66742; H01L 21/823412; H01L 21/823418; H01L 21/762

(57) ABSTRACT

A MOSFET includes a semiconductor substrate, which has a body and an upper layer. The upper layer is doped differently than the body. The body and the upper layer are of a same crystal structure and orientation. The MOSFET also includes a p-type FET on the upper layer of the substrate. The p-type FET includes p-doped source/drain structures that sandwich one or more channels and a p gate stack with a p-type work function metal. In one or more embodiments, the p-doped source/drain structures are of the same crystal structure and orientation as the upper layer of the substrate and directly contact the upper layer of the substrate. In one or more embodiments, the upper layer of the substrate is doped differently than the p-doped source/drain structures, such that the p-doped source/drain structures and the upper layer of the substrate form pn-type diodes.

### BACKGROUND

The present invention relates to the electrical, electronic, and computer arts, and more specifically, to semiconductor device fabrication.

Complementary metal-oxide-semiconductor (C-MOS) field effect transistor (FET) fabrication is a well-known technology that involves depositing and etching layers of semiconductors, dielectrics, and conductors. A typical FET has a pair of semiconductor source/drain structures that are mechanically and electrically connected by a gate structure, which includes a semiconductor channel and a metal/dielectric gate stack. Some FETs have the gate stack partly or entirely surrounding the channel. Other FETs have the gate stack adjacent to the channel. In some FETs, the channel includes multiple mechanically distinct semiconductor structures. The source/drain structures and the gate structure are formed on a semiconductor substrate.

Typically, the source/drain structures and the gate structure are electrically isolated from the substrate so as to mitigate or eliminate undesirable leakage current, i.e. current through the FET when it is supposed to be turned off. One type of electrical isolation is a bottom dielectric isolator layer, which interposes a dielectric material (e.g., an oxide or organosilicate) between the substrate and the working structures of the FET. In typical configurations, a complete bottom dielectric isolator layer prevents growing the source/drain structures epitaxially from the substrate.

### SUMMARY

Principles of the invention provide techniques for enabling bottom isolation and epitaxial strain of FET (field effect transistor) source/drain structures.

In one aspect, an exemplary metal-oxide-semiconductor field effect transistor (FET) structure includes a substrate. The substrate includes a first semiconductor, which has a body and an upper layer. The upper layer of the substrate is doped differently than the body of the substrate, and the body and the upper layer are of a same crystal structure and orientation. The MOSFET also includes a p-type FET on the upper layer of the substrate. The p-type FET includes p-doped source/drain structures that sandwich one or more channels and a p gate stack with a p-type work function metal. In one or more embodiments, the p-doped source/drain structures are of the same crystal structure and orientation as the upper layer of the substrate and directly contact the upper layer of the substrate. In one or more embodiments, the upper layer of the substrate is doped differently than the p-doped source/drain structures, such that the p-doped source/drain structures and the upper layer of the substrate form pn-type diodes.

According to another aspect, an exemplary method for fabricating a field effect transistor includes obtaining a precursor structure. The precursor structure includes an intrinsic semiconductor substrate; and a stack, atop the substrate, which includes at least one semiconductor channel, sacrificial material surrounding the semiconductor channel, and amorphous silicon. In one or more embodiments, a portion of an upper surface of the substrate is exposed adjacent to the stack. The exemplary method also includes n-doping the exposed portion of the substrate, and epitaxially growing a p-doped source/drain structure from the n-doped exposed portion of the substrate, adjacent to the stack.

In view of the foregoing, techniques of the present invention can provide substantial beneficial technical effects. For example, one or more embodiments provide one or more of:

A bottom-isolated source/drain structure, in a PFET structure, that also is epitaxially grown from a substrate of the structure and thereby epitaxially strained.

Bottom isolation of a source/drain structure, without having a bottom dielectric isolation layer under the source/drain structure.

Some embodiments may not have these potential advantages and these potential advantages are not necessarily required of all embodiments. These and other features and advantages of the present invention will become apparent from the following detailed description of illustrative embodiments thereof, which is to be read in connection with the accompanying drawings.

### BRIEF DESCRIPTION OF THE DRAWINGS

FIG. 1 depicts a complementary metal-oxide-semiconductor field effect transistor (C-MOSFET) that has an epitaxially strained p-type source/drain structure (p-S/D), which is electrically isolated from its substrate without a bottom dielectric isolation layer, according to exemplary embodiments.

FIG. 2 depicts a complementary metal-oxide-semiconductor field effect transistor (C-MOSFET) that has an epitaxially strained p-type source/drain structure (p-S/D), which is electrically isolated from its substrate without a bottom dielectric isolation layer, according to exemplary embodiments.

FIG. 3 depicts a complementary metal-oxide-semiconductor field effect transistor (C-MOSFET) that has an epitaxially strained p-type source/drain structure (p-S/D), which is electrically isolated from its substrate without a bottom dielectric isolation layer, according to exemplary embodiments.

FIG. 4 depicts a complementary metal-oxide-semiconductor field effect transistor (C-MOSFET) that has an epitaxially strained p-type source/drain structure (p-S/D), which is electrically isolated from its substrate without a bottom dielectric isolation layer, according to exemplary embodiments.

FIG. 5 depicts steps of a method for fabricating the C-MOSFET shown in FIG. 1, according to exemplary embodiments.

FIG. 6 through FIG. 13 depict intermediate structures formed by the method shown in FIG. 5, according to exemplary embodiments.

### DETAILED DESCRIPTION

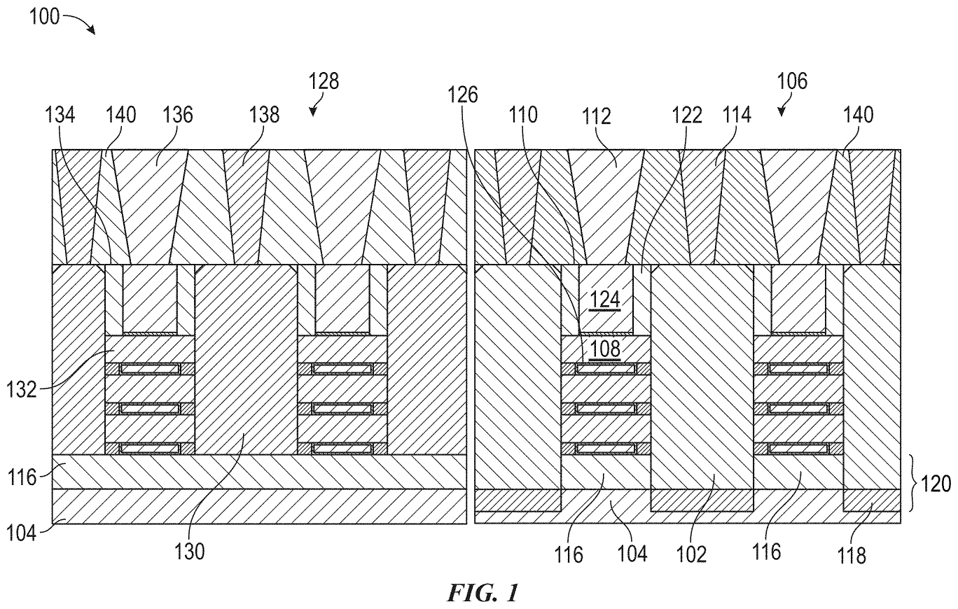

FIG. 1 depicts a complementary metal-oxide-semiconductor field effect transistor (C-MOSFET) 100 that has an epitaxially strained p-type source/drain structure (p-S/D) 102, which is electrically isolated from a substrate 104 of the C-MOSFET 100, according to exemplary embodiments. The p-S/D 102 is part of a PFET 106. The PFET 106 also includes one or more channels 108, a p gate stack 110, a gate contact 112, source/drain contacts 114, and bottom dielectric isolators 116.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures.

As used herein, the term “conductivity type” denotes a dopant region being p-type or n-type. As further used herein, “p-type” refers to the addition of impurities to an intrinsic semiconductor that creates deficiencies of valence electrons. In a silicon-containing substrate, examples of p-type dopants, i.e., impurities include but are not limited to: boron, aluminum, gallium and indium. As used herein, “n-type” refers to the addition of impurities that contribute free electrons to an intrinsic semiconductor. Examples of n-type dopants, i.e., impurities in a silicon-containing substrate include but are not limited to antimony, arsenic and phosphorous.

“Epitaxy” or “epitaxial growth,” as used herein, refers to a process by which a layer of single-crystal or large-grain polycrystalline material is formed on an existing material with similar crystalline properties. One feature of epitaxy is that this process causes the crystallographic structure of the existing substrate or seed layer (including any defects therein) to be reproduced in the epitaxially grown material. Epitaxial growth can include heteroepitaxy (i.e., growing a material with a different composition from its underlying layer) or homoepitaxy (i.e., growing a material which includes the same composition as its underlying layer). Heteroepitaxy can introduce strain in the epitaxially grown material, as its crystal structure may be distorted to match that of the underlying layer. In certain applications, such strain may be desirable. In an epitaxial deposition process, the chemical reactants provided by the source gases are controlled and the system parameters are set so that the depositing atoms arrive at the deposition surface of the semiconductor substrate with sufficient energy to move around on the surface and orient themselves to the crystal arrangement of the atoms of the deposition surface. Therefore, an epitaxial semiconductor material may have the same crystalline characteristics as the deposition surface on which it may be formed. For example, an epitaxial semiconductor material deposited on a {100} crystal surface may take on a {100} orientation. In some embodiments, epitaxial growth and/or deposition processes may be selective to forming on semiconductor surfaces, and may not deposit material on dielectric surfaces, such as silicon dioxide or silicon nitride surfaces.

A number of different precursors may be used for the epitaxial deposition of the in situ doped semiconductor material. In some embodiments, the gas source for the deposition of an epitaxially formed in situ doped semiconductor material may include silicon (Si) deposited from silane, disilane, trisilane, tetrasilane, hexachlorodisilane, tetrachlorosilane, dichlorosilane, trichlorosilane, di silane and combinations thereof. In other examples, when the in situ doped semiconductor material includes germanium, a germanium gas source may be selected from the group consisting of germane, digermane, halogermane, dichlorogermane, trichlorogermane, tetrachlorogermane and combinations thereof. Examples of other epitaxial growth processes that can be employed in growing semiconductor layers described herein include rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE).

By “in-situ” it is meant that the dopant that dictates the conductivity type of doped layer is introduced during the process step, for example epitaxial deposition, that forms the doped layer. The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

As an exemplary subtractive process, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1st Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

In one or more embodiments, as shown in FIG. 1, the channels 108 comprise a nanosheet. The skilled worker is familiar with other variations of channel structures within FET structures. For example, in one or more embodiments, not shown in the drawing views, the channels 108 comprise a fin.

In one or more embodiments, as shown in FIG. 1, the p gate stack 110 is a gate-all-around (GAA) structure that includes spacers 122, one or more metals 124 (in one or more embodiments, an alloy of metals), and a high-k dielectric 126. The skilled worker is familiar with other variations of gate stack structures within FET structures.

Gate stacks in both nFET and pFET structures (in embodiments having both types of regions) include work function metal (WFM) layers. Non-limiting examples of suitable work function (gate) metals include p-type work function metal materials and n-type work function metal materials. P-type work function materials include compositions such as ruthenium, palladium, platinum, cobalt, nickel, and conductive metal nitride like TiN, WN, or any combination thereof. N-type metal materials include compositions such as hafnium, zirconium, titanium, tantalum, aluminum, metal carbides (e.g., hafnium carbide, zirconium carbide, titanium carbide, and aluminum carbide), aluminides, or any combination thereof.

The work function metal(s) may be deposited by a suitable deposition process, for example, ALD, CVD, PECVD, PVD, plating, and thermal or e-beam evaporation. Pinch-off of work function metal material between semiconductor fins is essentially avoided during deposition. The WFM layer is removed from one of the nFET and pFET regions in structures including both types of regions while the other region is protected. An SC1 etch, an SC2 etch or other suitable etch processes can be employed to remove the selected portion of the originally deposited WFM layer. A new WFM layer suitable for the region is then deposited. A device formed in the nFET region will accordingly include a WFM layer (gate electrode) having a first composition while a device in the pFET region will have a WFM layer having a second composition. For example, the WFM employed in an nFET region may be a Ti, Al, TiAl, TiAlC or TiAlC layer or a metal stack such as TiN/TiAl/TiN, TiN/TiAlC/TiN, TiN/TaAlC/TiN, or any combination of an aluminum alloy and TiN layers. The WFM layer employed in the pFET region may, for example, be a TiN, TiC, TaN or a tungsten (W) layer. The threshold voltage (Vt) of nFET devices is sensitive to the thickness of work function metals such as titanium nitride (TiN).

In one or more embodiments, the p gate stack 110 includes a high-k dielectric such as hafnium oxide (HfO), zirconium oxide (ZrO), or titanium oxide (TiO) with k on the order of 3-15 times higher than silicon dioxide (SiO2), e.g., on the order of 10-50, or similar suitable materials. Generally, oxides of refractory metals provide high-k dielectrics.

In one or more embodiments, the gate contact 112 and/or the source drain contacts 114 are composed partly or entirely of a metal. Contact metal may, for example, alternatively include tantalum (Ta), aluminum (Al), platinum (Pt), gold (Au), titanium (Ti), palladium (Pd) or any combination thereof. The contact metal may be deposited by, for example, CVD, PECVD, PVD, plating, thermal or e-beam evaporation, or sputtering. A planarization process such as CMP is performed to remove any excess of electrically conductive material (overburden) from the top surface of the structure.

In one or more embodiments, the gate contact 112 and/or the source drain contacts 114 are composed partly or entirely of polysilicon. The skilled worker is familiar with other variations of gate and source/drain contact structures within FET structures.

In one or more embodiments, the bottom dielectric isolator 116 is composed of, e.g., silicon dioxide, SiN, SiOC, or SiOCN.

An aspect of the invention is that the substrate 104 includes an upper layer, of which at least a portion 118 is n-doped (opposite doping to the p-S/D 102). Advantageously, n-doping the portion 118 of the substrate 104 produces a diode 120 between the portion 118 and the p-S/D 102. In normal operation of the PFET 106, the diode 120 is reverse biased. Reverse biasing the diode 120 electrically isolates the p-S/D 102 from the substrate 104.

The portion 118 of the substrate 104 can be n-doped by, for example, ion implantation of a dopant such as phosphorus or the like (in one or more embodiments, another Group V semiconductor may be used as a dopant). Ion implantation, with proper use of spacers to focus the implantation in a manner familiar to the skilled worker, advantageously limits the n-doping to the portion 118.

The C-MOSFET 100 also includes an NFET 128. The NFET 128 comprises n- type source/drain contacts (n-S/D) 130, channels 132, an n gate stack 134, a gate contact 136 and source/drain contacts 138, and the bottom dielectric isolator 116. Aside from choices of materials, which in one or more embodiments differ from those used for the PFET 106, in one or more embodiments the NFET 128 structure is generally similar to the PFET 106 structure, as shown in FIG. 1. In other embodiments, not shown in the drawing views, the NFET 128 structure is different than the PFET 106 structure. For example, the NFET 128 may have fins for the channels 132 whereas the PFET 106 has nanosheets for the channels 108; or the opposite. The skilled worker is familiar with other variations in C-MOSFET structures.

An interlayer dielectric 140 surrounds and supports the contacts 112, 114, 136, 138.

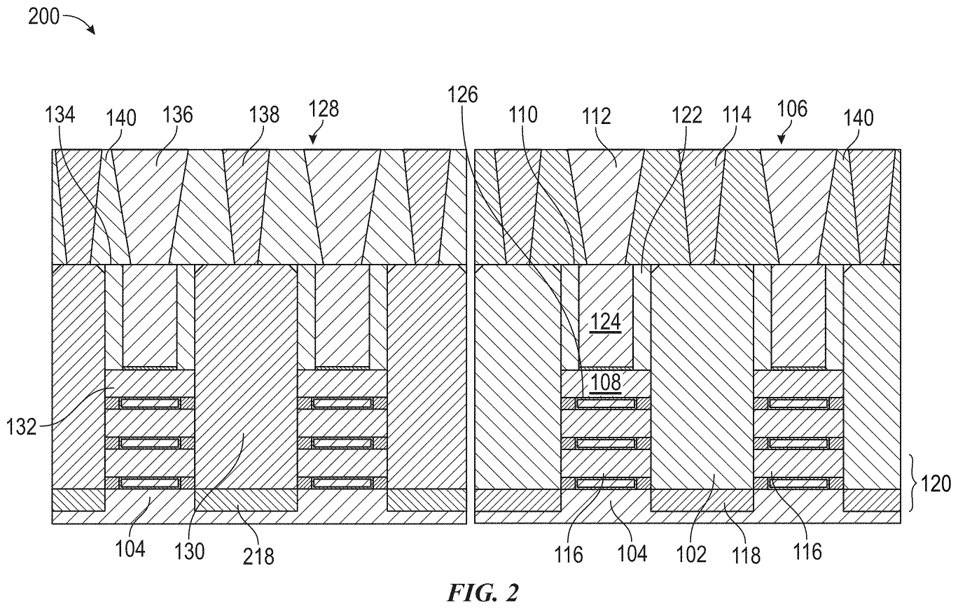

FIG. 2 depicts a complementary metal-oxide-semiconductor field effect transistor (C-MOSFET) 200 that has an epitaxially strained p-type source/drain structure (p-S/D) 102, which is electrically isolated from its substrate 104, according to exemplary embodiments. Many components of FIG. 2 are similar to those of FIG. 1, are similarly numbered, and detailed descriptions thereof are not repeated. The C-MOSFET 200 differs from the C-MOSFET 100 at least in the absence of any bottom dielectric isolator layer. Instead, in the C-MOSFET 200, upper portions 218 of the substrate 104 are p-doped immediately under the n-S/Ds 130 of the NFET 128.

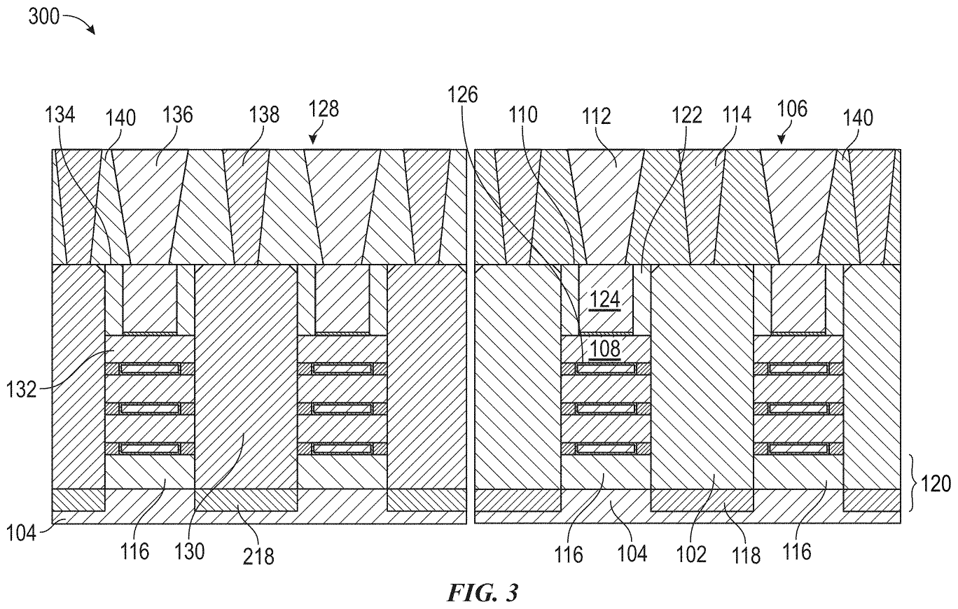

FIG. 3 depicts a complementary metal-oxide-semiconductor field effect transistor (C-MOSFET) 300 that has an epitaxially strained p-type source/drain structure (p-S/D) 102, which is electrically isolated from its substrate 104, according to exemplary embodiments. Many components of FIG. 3 are similar to those of FIG. 1 and FIG. 2, are similarly numbered, and detailed descriptions thereof are not repeated. The C-MOSFET 300 differs from the C-MOSFET 100 at least in the combined presence of bottom dielectric isolator 116 below the n gate stacks 134 and p-doped portions 218 of the substrate 104 immediately below the n-S/Ds 130.

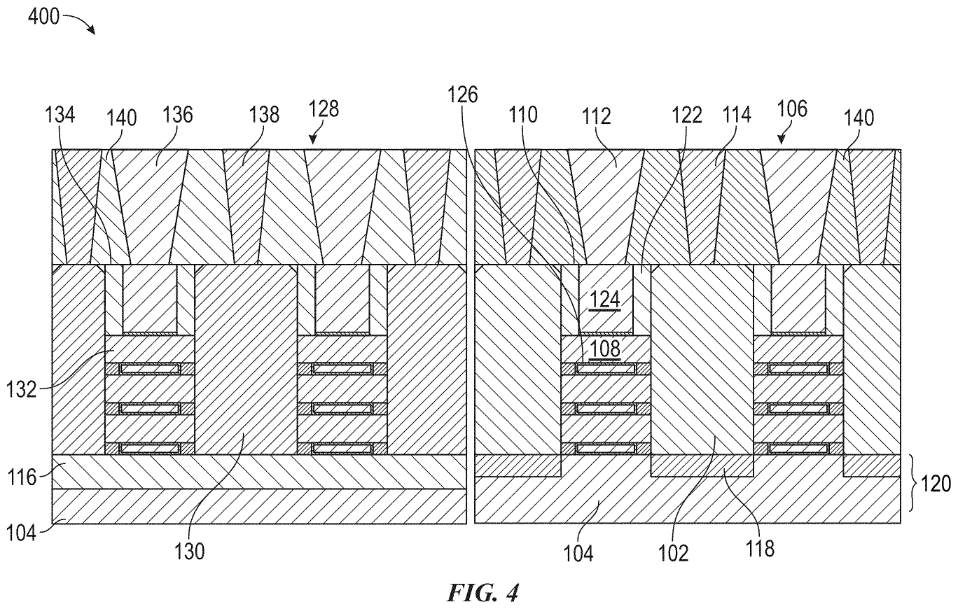

FIG. 4 depicts a complementary metal-oxide-semiconductor field effect transistor (C-MOSFET) 400 that has an epitaxially strained p-type source/drain structure (p-S/D) 102, which is electrically isolated from its substrate 104, according to exemplary embodiments. Many components of FIG. 3 are similar to those of FIG. 1 and FIG. 2, are similarly numbered, and detailed descriptions thereof are not repeated. The C-MOSFET 400 differs from the C-MOSFET 100 at least in that the bottom dielectric isolator 116 is present beneath the NFET 128 but not anywhere beneath the PFET 106.

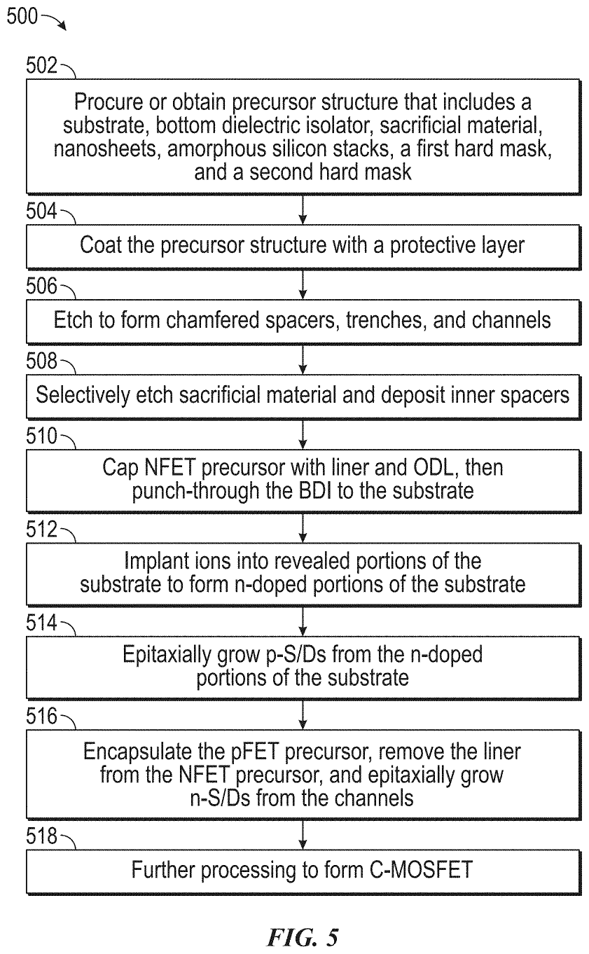

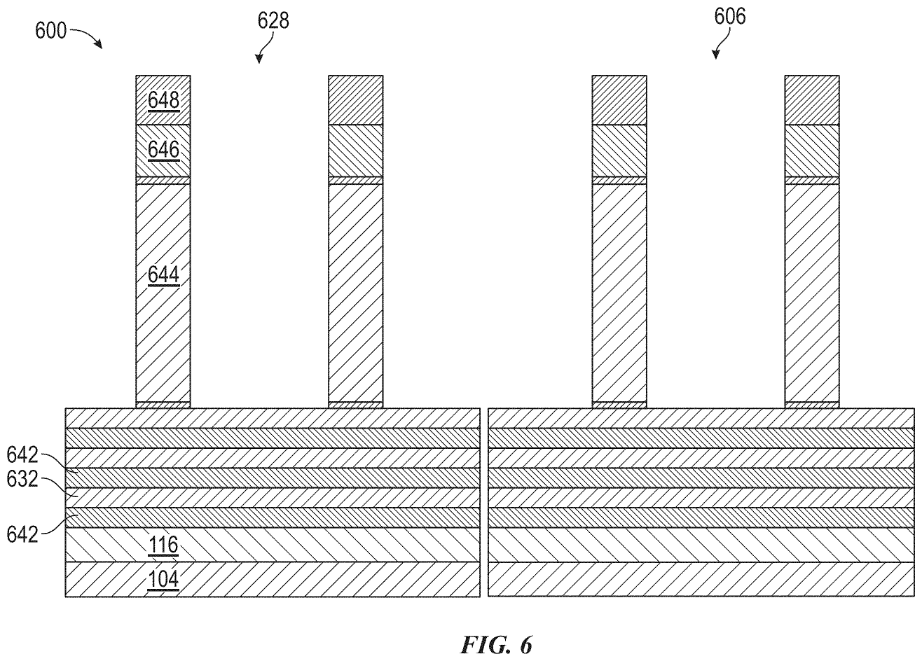

FIG. 5 depicts steps of a method 500 for fabricating the C-MOSFET 100 shown in FIG. 1, according to exemplary embodiments. FIG. 6 through FIG. 13 depict intermediate structures formed by the method shown in FIG. 5, according to exemplary embodiments.

Referring to FIG. 5 and FIG. 6, at 502, obtain or form a precursor structure 600 that includes the substrate 104 supporting layers of the bottom dielectric isolator 116, a sacrificial material 642, and nanosheets 632. Atop the layered structure are amorphous silicon stacks 644, a first hard mask 646 (e.g., silicon nitride), and a second hard mask 648 (e.g., silicon dioxide). The precursor structure 600 includes a PFET precursor 606 and an NFET precursor 628.

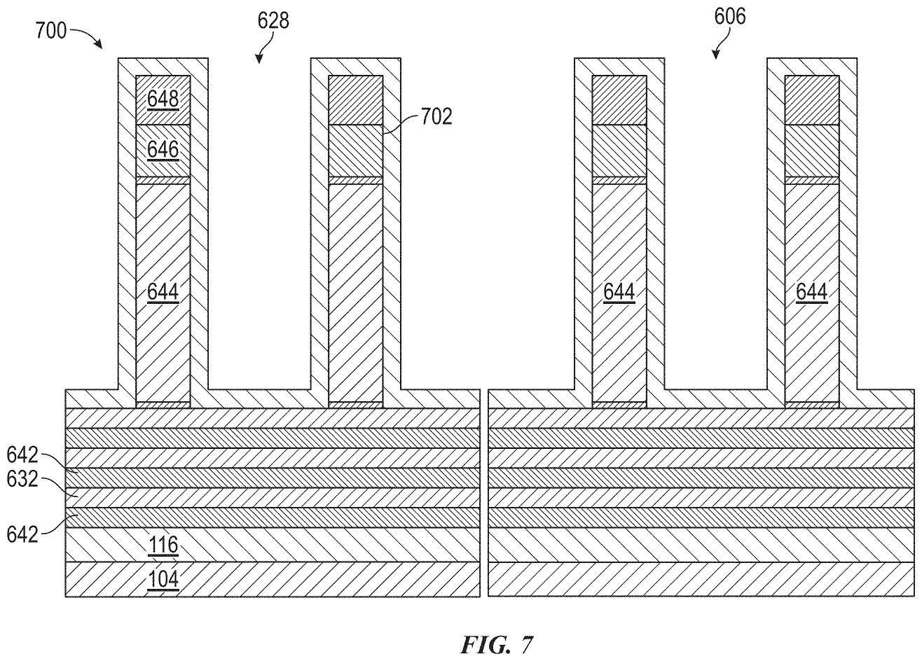

At 504, referring also to FIG. 7, form an intermediate structure 700 by coating the precursor structure 600 with a protective layer 702, which is composed of, e.g., a dielectric material such as silicon nitride, a silicon oxide, SiBCN, SiCOH, SiOCN.

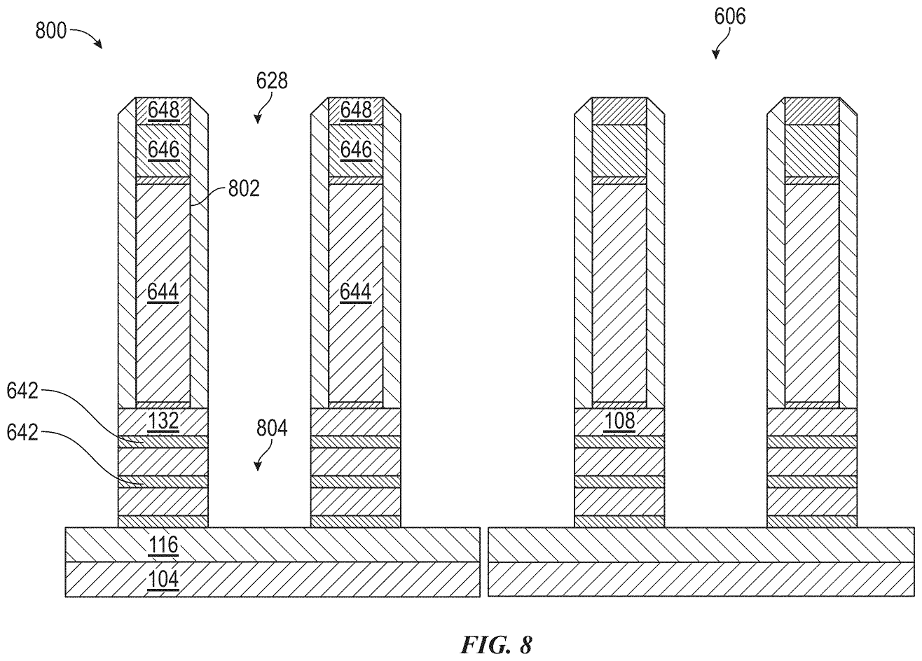

At 506, referring also to FIG. 8, form an intermediate structure 800 by etching the intermediate structure 700 to form chamfered spacers 802, trenches 804, and channels 108 and 132.

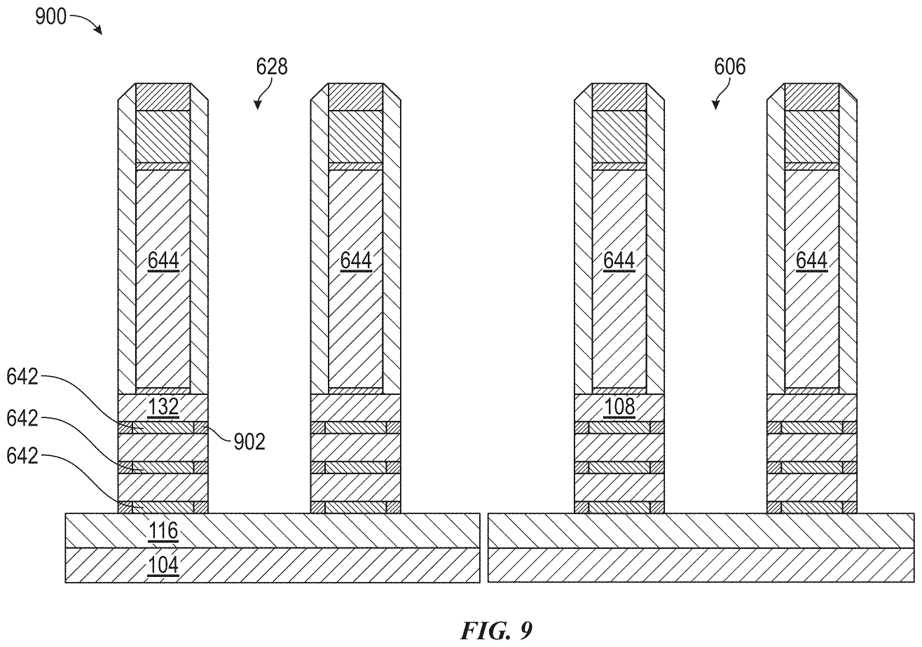

At 508, referring also to FIG. 9, form an intermediate structure 900 by selectively etching the sacrificial material 642 and depositing inner spacers 902.

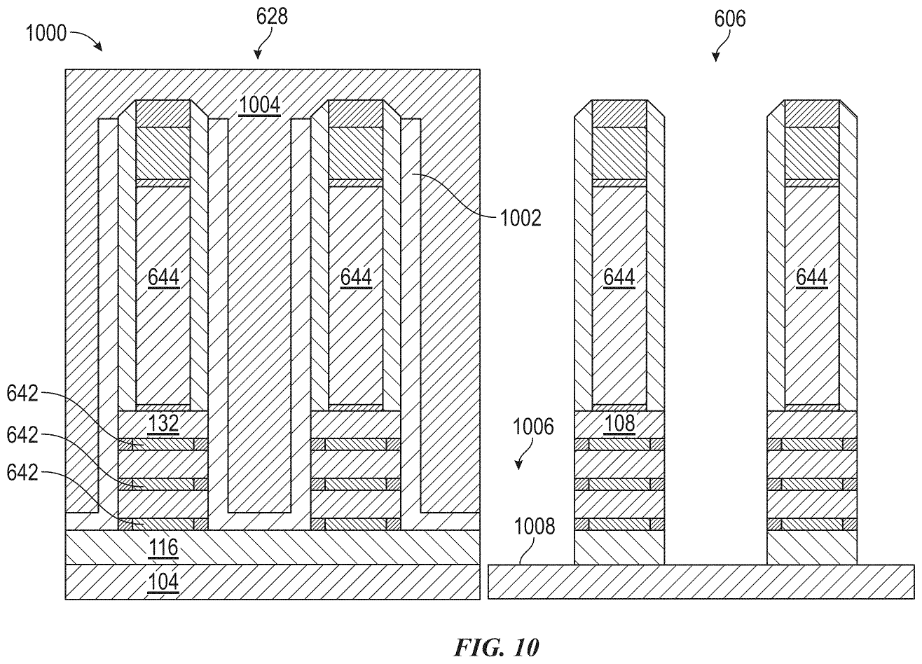

At 510, referring also to FIG. 10, form an intermediate structure 1000 by capping the NFET precursor 628 with a liner 1002 and organic dielectric layer 1004, then reactive ion etching exposed portions of the BDI 116 in the PFET precursor 606 to form punch-throughs 1006 that reveal portions 1008 of the substrate 104.

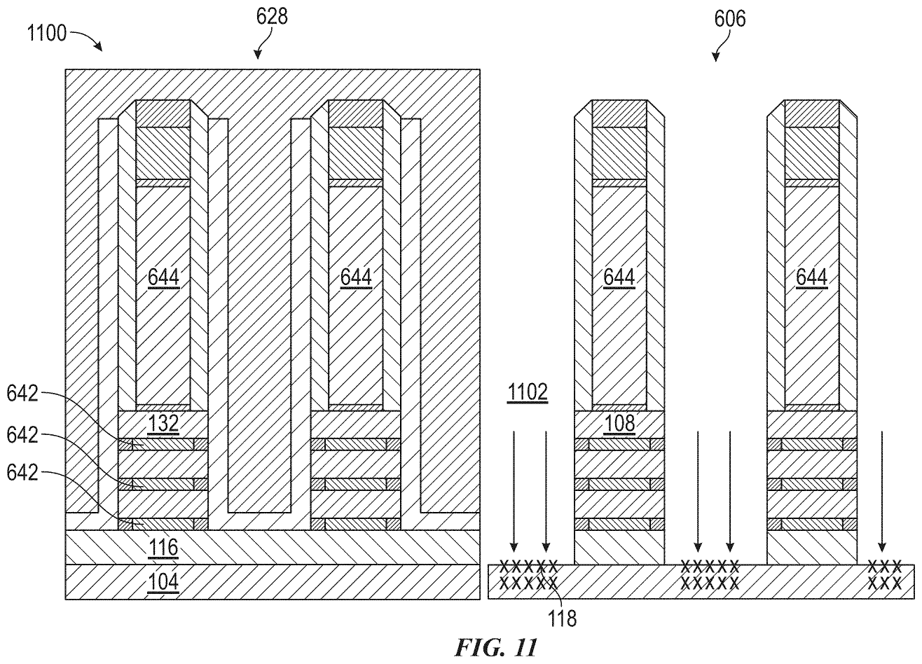

At 512, referring also to FIG. 11, implant ions 1102 into the revealed portions 1008 (seen in FIG. 10) of the substrate 104 to form an intermediate structure 1100 that has n-doped portions 118 of the substrate 104.

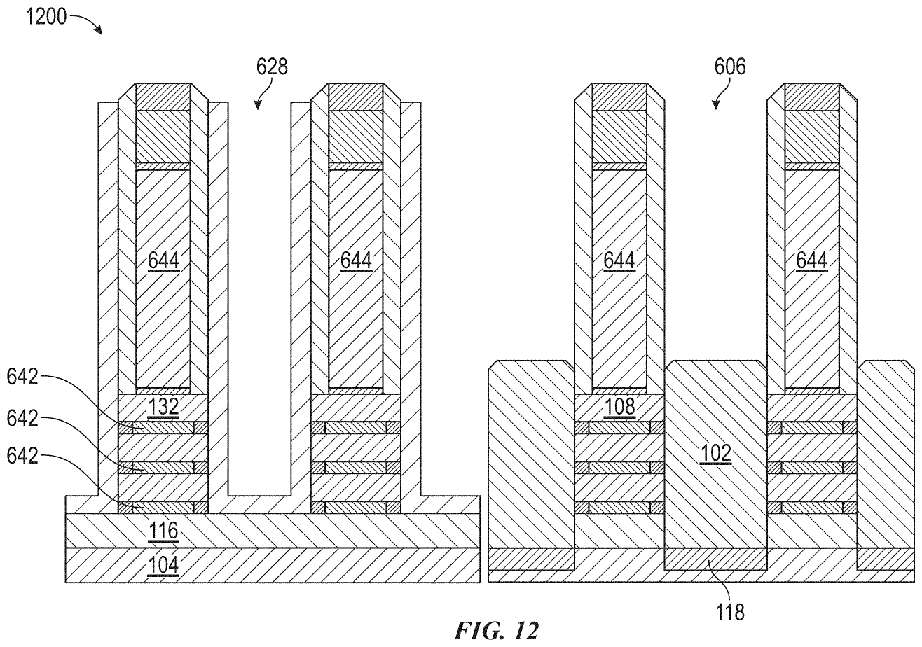

At 514, referring also to FIG. 12, remove the ODL 1004 from NFET precursor 628 and form an intermediate structure 1200 by epitaxially growing p-S/Ds 102 in the PFET precursor 606 from the n-doped portions 118 of the substrate 104. Advantageously, epitaxial growth of the p-S/Ds 102 from the substrate 104 introduces epitaxial strain in the p-S/Ds, which enhances their hole conductivity for reasons that the skilled worker will appreciate. The liner 1002 prevents simultaneously growing n-S/Ds in the NFET precursor 628.

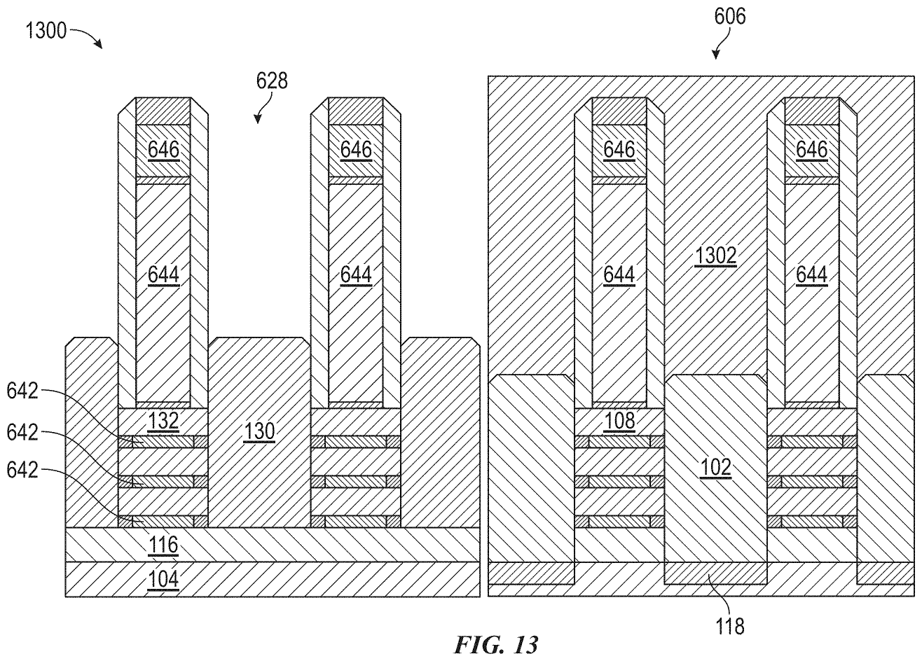

At 516, referring also to FIG. 13, form an intermediate structure 1300 by encapsulating the pFET precursor 606 with an OPL 1302, removing the liner from the NFET precursor 628, and then epitaxially growing n-S/Ds 130 from the channels 132.

The skilled worker will apprehend such additional actions, known in the art, that are useful at step 518, further processing the intermediate structure 1300 to form the C-MOSFET 100 that is shown in FIG. 1.

In view of FIG. 1 and FIG. 5 through FIG. 13, and further in view of the individual discussions, above, of different process steps for FIG. 2, FIG. 3, and FIG. 4, the skilled worker will apprehend how to fabricate the structures 200, 300, and 400 that are shown in FIG. 2, FIG. 3, and FIG. 4.

Given the discussion thus far, it will be appreciated that, in general terms, an exemplary metal-oxide-semiconductor field effect transistor (FET) structure 100, 200, 300, or 400 includes a substrate 104. The substrate includes a first semiconductor, which has a body and an upper layer 118. The upper layer of the substrate is doped differently than the body of the substrate, and the body and the upper layer are of a same crystal structure and orientation. The MOSFET also includes a p-type FET 106 on the upper layer of the substrate. The p-type FET includes p-doped source/drain structures 102 that sandwich one or more channels 108 and a p gate stack 110 with a p-type work function metal 124. In one or more embodiments, the p-doped source/drain structures are of the same crystal structure and orientation as the upper layer of the substrate and directly contact the upper layer of the substrate. In one or more embodiments, the upper layer of the substrate is doped differently than the p-doped source/drain structures, such that the p-doped source/drain structures and the upper layer of the substrate form pn-type diodes.

In one or more embodiments, a bottom dielectric isolation 116 is present between the p gate stack and the upper layer of the substrate.

In one or more embodiments, the exemplary MOSFET also includes an n-type FET 128 on the upper layer of the substrate, at a position laterally offset from the p-type FET. The n-type FET includes n-doped source/drain structures and an n gate stack with an n-type work function metal. In one or more embodiments, the bottom dielectric isolation 116 is present between the n-doped source/drain structures and the upper layer of the substrate. In one or more embodiments, the upper layer 218 of the substrate is doped differently than the n-doped source/drain structures immediately under the n-doped source/drain structures, such that the n-doped source/drain structures and the upper layer of the substrate form an np-type diode. In one or more embodiments, a second bottom dielectric isolation is present between the n gate stack and the upper layer of the substrate. In one or more embodiments, there is no bottom dielectric isolation between the n-doped source/drain structures and the substrate. In one or more embodiments, the upper layer of the substrate is doped differently than the n-doped source/drain structures immediately under the n-doped source/drain structures, such that the n-doped source/drain structures and the upper layer of the substrate form an np-type diode. In one or more embodiments, the n-doped source/drain structures are of the same crystal structure and orientation as the upper layer of the substrate.

In one or more embodiments, the exemplary MOSFET does not include a first bottom dielectric isolation between the p gate stack and the upper layer of the substrate. An n-type FET is on the upper layer of the substrate, at a position laterally offset from the p-type FET. The n-type FET includes n-doped source/drain structures and an n gate stack with an n-type work function metal. In one or more embodiments, a second bottom dielectric isolation is present between the n-doped source/drain structures and the upper layer of the substrate. In one or more embodiments, the upper layer of the substrate is doped differently than the n-doped source/drain structures immediately under the n-doped source/drain structures, such that the n-doped source/drain structures and the upper layer of the substrate form an np-type diode. In one or more embodiments, a second bottom dielectric isolation is present between the n gate stack and the upper layer of the substrate. In one or more embodiments, there is no bottom dielectric isolation between the n-doped source/drain structures and the substrate. In one or more embodiments, the upper layer of the substrate is doped differently than the n-doped source/drain structures immediately under the n-doped source/drain structures, such that the n-doped source/drain structures and the upper layer of the substrate form an np-type diode.

In one or more embodiments, the n-doped source/drain structures are of the same crystal structure and orientation as the upper layer of the substrate.

In one or more embodiments, the one or more channels of the p-type FET include a nanosheet.

In one or more embodiments, the p-doped source/drain structures are laterally strained by crystal structure alignment to the substrate.

According to another aspect, an exemplary method 500 for fabricating a field effect transistor includes, at 502, obtaining a precursor structure. The precursor structure includes an intrinsic semiconductor substrate; and a stack, atop the substrate, which includes at least one semiconductor channel, sacrificial material surrounding the semiconductor channel, and amorphous silicon. In one or more embodiments, a portion of an upper surface of the substrate is exposed adjacent to the stack. The exemplary method also includes, at 512, n-doping the exposed portion of the substrate, and, at 514, epitaxially growing a p-doped source/drain structure from the n-doped exposed portion of the substrate, adjacent to the stack. In one or more embodiments, the method also includes, at 510, etching a bottom dielectric isolator layer to expose the exposed portion of the substrate.

In one or more embodiments, the method also includes p-doping a second exposed portion of the substrate, adjacent to a second stack, and epitaxially growing an n-doped source/drain structure from the second exposed portion of the substrate, adjacent to the second stack. In one or more embodiments, the method also includes etching a bottom dielectric isolator layer to expose the second exposed portion of the substrate.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A metal-oxide-semiconductor field effect transistor (FET) structure comprising:
a substrate, comprising a first semiconductor, which has a body and an upper layer, wherein the upper layer of the substrate is doped differently than the body of the substrate, and wherein the body and the upper layer are of a same crystal structure and orientation; and
a p-type FET on the upper layer of the substrate, the p-type FET comprising p-doped source/drain structures that sandwich one or more channels and a p gate stack with a p-type work function metal, wherein the p-doped source/drain structures are of the same crystal structure and orientation as the upper layer of the substrate and directly contact the upper layer of the substrate;
wherein the upper layer of the substrate is doped differently than the p-doped source/drain structures, such that the p-doped source/drain structures and the upper layer of the substrate form pn-type diodes.

2. The structure of claim 1, wherein a first bottom dielectric isolation is present between the p gate stack and the upper layer of the substrate.

3. The structure of claim 2, further comprising:
an n-type FET on the upper layer of the substrate, at a position laterally offset from the p-type FET, wherein the n-type FET comprises n-doped source/drain structures and an n gate stack with an n-type work function metal.

4. The structure of claim 3, wherein a second bottom dielectric isolation is present between the n-doped source/drain structures and the upper layer of the substrate.

5. The structure of claim 3, wherein the upper layer of the substrate is doped differently than the n-doped source/drain structures immediately under the n-doped source/drain structures, such that the n-doped source/drain structures and the upper layer of the substrate form an np-type diode.

6. The structure of claim 3, wherein a second bottom dielectric isolation is present between the n gate stack and the upper layer of the substrate.

7. The structure of claim 6, wherein there is no bottom dielectric isolation between the n-doped source/drain structures and the substrate,
wherein the upper layer of the substrate is doped differently than the n-doped source/drain structures immediately under the n-doped source/drain structures, such that the n-doped source/drain structures and the upper layer of the substrate form an np-type diode.

8. The structure of claim 7, wherein the n-doped source/drain structures are of the same crystal structure and orientation as the upper layer of the substrate.

9. The structure of claim 1, further comprising:
an n-type FET on the upper layer of the substrate, at a position laterally offset from the p-type FET, wherein the n-type FET comprises n-doped source/drain structures and an n gate stack with an n-type work function metal.

10. The structure of claim 9, wherein a second bottom dielectric isolation is present between the n-doped source/drain structures and the upper layer of the substrate.

11. The structure of claim 9, wherein the upper layer of the substrate is doped differently than the n-doped source/drain structures immediately under the n-doped source/drain structures, such that the n-doped source/drain structures and the upper layer of the substrate form an np-type diode.

12. The structure of claim 9, wherein a second bottom dielectric isolation is present between the n gate stack and the upper layer of the substrate.

13. The structure of claim 12, wherein there is no bottom dielectric isolation between the n-doped source/drain structures and the substrate,
wherein the upper layer of the substrate is doped differently than the n-doped source/drain structures immediately under the n-doped source/drain structures, such that the n-doped source/drain structures and the upper layer of the substrate form an np-type diode.

14. The structure of claim 13, wherein the n-doped source/drain structures are of the same crystal structure and orientation as the upper layer of the substrate.

15. The structure of claim 1, wherein the one or more channels of the p-type FET comprise a nanosheet.

16. The structure of claim 1, wherein the p-doped source/drain structures are laterally strained by crystal structure alignment to the substrate.

17. A method for fabricating a field effect transistor, the method comprising:
obtaining a precursor structure that comprises:
an intrinsic semiconductor substrate; and
a stack, atop the substrate, which comprises at least one semiconductor channel, sacrificial material surrounding the semiconductor channel, and amorphous silicon,
wherein a portion of an upper surface of the substrate is exposed adjacent to the stack;
n-doping the exposed portion of the substrate; and
epitaxially growing a p-doped source/drain structure from the n-doped exposed portion of the substrate, adjacent to the stack.

18. The method of claim 17, further comprising:
etching a bottom dielectric isolator layer to expose the exposed portion of the substrate.

19. The method of claim 17, further comprising:
p-doping a second exposed portion of the substrate, adjacent to a second stack; and
epitaxially growing an n-doped source/drain structure from the second exposed portion of the substrate, adjacent to the second stack.

20. The method of claim 19, further comprising:
etching a bottom dielectric isolator layer to expose the second exposed portion of the substrate.
